(19) United States
(12) Patent Application Publication
(10) Pub. No.: US 2008/0171133 A1
(43) Pub. Date: Jul. 17, 2008

(54) Method For the Production of C-Plane Oriented Gan Substrates or AlxGa1-xN Substrates

(75) Inventors: Eberhard Richter, Berlin (DE); Gunther Trankle, Berlin (DE); Markus Weyers, Wildau (DE)

Correspondence Address: FOLEY AND LARDNER LLP;SUITE 500, 3000 K STREET NW, WASHINGTON, DC, 20007, US

(73) Assignee: Freiberger Compound Materials GMBH, Freiberger (DE)

(21) Appl. No.: 11/814,331

(22) PCT Filed: Jan. 18, 2006
(86) PCT No.: PCT/EP2006/050272

§ 371 Date: Oct. 25, 2007

(30) Foreign Application Priority Data
Jan. 24, 2005 (DE) 10 2005 003 884.0

(51) Int. Cl. B05D 5/12; C30B 33/00; C30B 31/00

(52) U.S. Cl. 427/58; 117/2; 117/84

(57) ABSTRACT

The invention relates to a method for producing c-plane GaN substrates or AlₓGa₁₋ₓN substrates using an original substrate. Said method is characterized by the following steps: a tetragonal (100)-oriented or (−100)-oriented original LiAlO₂ substrate is used; said original substrate is nitrided in a nitrogen compound-containing atmosphere at temperatures lying below the decomposition temperature of LiAlO₂; a nucleation layer is grown at temperatures ranging between 500° C. and 700° C. by adding GaCl or AlCl or a mixture of GaCl and AlCl in a nitrogen compound-containing atmosphere; single-crystalline c-plane-oriented GaN or AlₓGa₁₋ₓN is grown on the nucleation layer at temperatures ranging between 900° C. and 1050° C. by means of hydride vapor phase epitaxy (HVPE) with GaCl or AlCl or a GaCl/AlCl mixture in a nitrogen compound-containing atmosphere; and the substrate is cooled.

The invention relates to a process for preparing c-plane GaN or AlₓGa₁₋ₓN substrates with using a starting substrate.

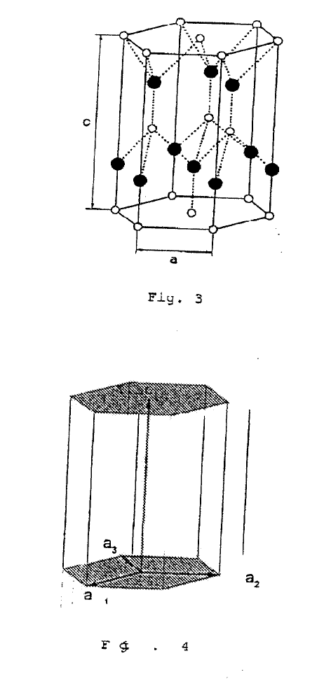

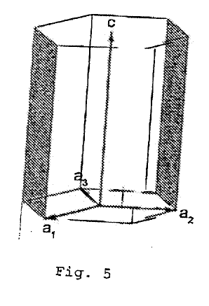

Layered structures from group III nitrides (Ga, Al, In) form the basis of a variety modern devices for high frequency power electronics (communication systems on the basis of HFETs (heterojunction field effect transistor), sensor systems, radiation resistant aerospace electronics) and for optoelectronics (e.g. UV-, blue and white light-emitting diodes (LEDs) and blue laser diodes for illumination, letter press, display, storage and communication transmitting applications as well as medical applications). Such layers are typically produced by metal-organic vapour phase epitaxy (MOVPE) as well as by molecular beam epitaxy (MBE) on a starting substrate. Here, a growth direction most commonly applied is the c-direction (c-plane Ga(Al, In)N). FIG. 3 shows a scheme of the GaN lattice with point locations for nitrogen (large black circles) and for gallium (small open circles), FIG. 4 shows the base vectors a1 [2-10], a2 [−120] and a3 [−1-10] in the c-plane (0001) and of basic vector c [001]. The grey-filled areas show c-planes, which lie in the growth plane for c-plane oriented growth. The growth direction is the [001]-direction. The less commonly used m-plane (m-plane Ga(Al, In)N) basically differs therefrom due to resulting other physical properties and device characteristics. FIG. 5 shows the basic vectors a1 [2-10], a2 [−120] and a3 [−1-10] in the c-plane (0001) and the basic vector c [001]. The grey-filled areas show m-planes, which lie in the growth plane for m-plane oriented growth. The growth direction then is the <1-10>-direction.

An ideal starting substrates shall belong to the same material system as the layers grown thereon, i.e. should be, e.g., a GaN substrate in the present case. Thereby, requirements for a defect-free growth, i.e. a sufficiently good to perfect lattice mismatch (homoepitaxy), and an adaptation of the thermal extension coefficients are satisfied in advance. Depending on the application a doping is advantageous, which renders the substrate n-conductive, semi-insulating or p-conductive.

Contrary to other semiconductors, e.g. silicon (Si) and gallium arsenide (GaAs), up to now the production of GaN crystals having diameters of 50.8 mm or higher by conventional single crystal growth is not successful. Promising processes such as growth from a melt under high pressures and temperatures (HPSG—high pressure solution growth) result in crystal platelets in the order of cm² only. Hitherto, growth by sublimation is not successful either. Hitherto, layer structures therefore are grown mostly on foreign substrates, such as e.g. sapphire and silicon carbide (SiC), epitaxially (heteroepitaxy). This is disadvantageous e.g. with respect to achievable dislocation densities and resulting bowings or warpages.

Therefore, it was tried to produce GaN starting substrates, which either remain on the starting material of the starting substrate, or which are removed after the growth in a further process.

U.S. Pat. No. 5,625,202 describes the growth of group III nitride-layers for producing LEDs or LDs on a variety of different starting substrates. These starting materials are described as oxide compound crystals having modified Wurtzite structure and include, among others, lithium aluminum oxide. Here, the group III nitride-layers, e.g. GaN, remain on the starting substrate. Due to different thermal extension coefficients, this always leads to a strong bowing of the layers. No free-standing GaN or AlGaN layers are produced.

U.S. Pat. No. 6,156,581 describes the growth of (Ga, Al, In)-nitride-layers on a foreign substrate as a base layer for the subsequent production of device layer structures through MOVPE or MBE. For this, gaseous (Ga, Al, In)-chloride reacts in a nitrogen compound-containing atmosphere on a substrate to yield (Ga, Al, In)N. The layer thickness may be 2 μm or more. The document lists a number of possible alternative starting substrates, including lithium aluminate. Further, it does not exclude that, also, the starting substrate may be separated under certain conditions, and that free-standing (Ga, Al, In)N-pieces may then be obtained.

However, specific growth conditions are indicated only for the growth on sapphire. Even there, it is not exactly specified how to accomplish the single-crystalline growth on the starting substrate. By the expression lithium aluminate, neither the crystal composition (Li₅AlO₄, LiAl₅O₈ or LiAlO₂) nor the crystal structure (Li₅AlO₄: ortho-rhombic, Li₅AlO₈: cubic, Li₅AlO₂: ortho-rhombic or tetragonal), nor the necessary orientation is indicated, so that there is no enablement.

U.S. Pat. No. 6,218,280 B1 describes the growth of c-plane GaN on a lithium gallate substrate (LiGaO₂), wherein nitridation is carried out by MOVPE first, and then a GaN starting layer is deposited. Then, with HVPE a further GaN layer is deposited, which is finally overgrown again by a MOVPE-grown GaN layer. The starting substrate may then be separated, or may be wet-chemically removed. The document proposes a number of further possible starting substrates, inter alia also ortho-rhombic LiAlO₂. The selection of the starting substrates is limited to oxide crystals with ortho-rhombic structure, wherein specific process conditions again are indicated for lithium gallate only. The process is very complex and cumbersome, because a combination of MOVPE and HVPE (H-MOVPE) is required. A direct growth by HVPE is excluded, because the contact of the starting substrate with hydrogen chloride (HCl) must be avoided.

The article of Xu et al. with the title “γ-LiAlO₂ single crystal: a novel substrate for GaN epitaxy” in Journal of Crystal Growth, Vol. 193, 1998, pages 127ff. and “MOCVD Growth of GaN on LiAlO₂ substrates” in Phys. Stat. Sol (a) Vol. 176, 1999, pages 589ff. propose the use of a LiAlO₂ substrate with subsequent nitridation and GaN layer growth in the MOVPE. However, the MOVPE-growth is not sufficiently fast, in order to thereby produce thicker GaN layers as required for free-standing GaN layers.

According to the articles of Waltereit et al. with the titles “Nitride semiconductors free of electrostatic fields for efficient white light-emitting diodes” in Letters to Nature, Vol. 406, 2000, pages 865ff. and “Grwoth of M-plane GaN (1-100): A Way to Evade Electrical Polarization in Nitrides” in Phys. Stat. Sol. (a) Vol. 180, 2000, pages 133ff., the deposition of thin m-plane oriented GaN layers on LiAlO₂ by MBE shall be carried out. The growth rates here are low (˜0,5 μm/h).

The process could enable only starting layers for the HVPE-growth of m-plane GaN layers. However, c-plane oriented GaN layers or substrates can not be produced in this manner, because the m-plane orientation is prescribed by the starting layer.

According to U.S. Pat. No. 6,648,966 B2, the growth of m-plane oriented GaN substrates with diameters of 50 mm and more on tetragonal γ-LiAlO₂ by HVPE and the separation of the LiAlO₂ in a subsequent wet-chemical etching step are carried out. For this, a pre-treatment step with GaCl and without a nitrogen-containing gas is carried out first. After the growth, the LiAlO₂-starting substrate preliminary remains at the GaN layer and is then separated ex-situ in hot hydrochloride acid. The process does not allow the production of c-plane GaN substrates. The thus obtained m-plane oriented substrates must be separated in a subsequent etching step, whereby bowings or warpages, which are imposed into the GaN layer during cooling, remain.

The object of the invention is to provide a process, which enables a simple production of large area-sized n- or p-doped, semi-insulating doped or non-doped c-plane GaN- or AlₓGa₁₋ₓN-substrates.

According to the present invention, the object is solved by the features of claim 1. Preferred embodiments are subject to the subclaims.

The whole process takes place in a hydride vapour phase epitaxy (HVPE) apparatus for group III nitrides, which is characterized in that a nitrogen compound-containing atmosphere provides nitrogen required for growth and for surface stabilization on the substrate, and that the group III element required for growth on the substrate is provided by a gaseous metal chloride formed by a hydrogen chloride (HCl) and a metal of the third main group (Al, Ga, In).

Doping may be realized by suitable starting substances, i.e. in the most simple case by HCl and the corresponding element: silicon (Si) for n-doping, iron (Fe) for semi-insulating doping, and magnesium (Mg) for p-doping.

According to the process steps:
tetragonal, (100) or (−100) oriented lithium aluminum oxide (LiAlO₂) is used as starting substrate. LiAlO₂ is polymorph, and the crystal structure can be distinguished by a simple X-ray detraction measurement of the angle 2theta at the 002 reflex: tetragonal: 34.646 degrees; ortho-rhombic: 33.929 degrees. Deviations of the orientation of the surface from the exact orientation (so-called misorientation) up to a few degrees are tolerated by the process and only lead to differences in the obtained crystal quality of the GaN or AlₓGa₁₋ₓN grown thereon. The starting substrate typically has a diameter of 50.8 mm. The process is easily applicable to other substrate sizes and substrate shapes.
The LiAlO₂ is nitrided in a nitrogen compound-containing atmosphere at temperatures below the thermal decomposition temperature of LiAlO₂. That is, the temperatures lie below ca. 900° C., because then vaporization of Li in the form LiO₂ substantially starts.
After nitridation, the temperature is adjusted for the formation of a nucleation layer (ca. 550° C. to 650° C.), and GaN seeds are formed by supplying GaCl in a nitrogen compound-containing atmosphere.
This temperature also lies below the thermal decomposition temperature of LiAlO₂. Here, by offering GaCl in the nitrogen compound-containing atmosphere, GaN seeds are formed which grow to small GaN crystallites on the LiAlO₂. These already have the (0001)-orientation in growth direction required for c-plane growth. The size of the crystallites typically lie between 10 and 150 nm. Such a starting layer generally is crystallographically denoted as nucleation layer, seed layer or sometimes also as buffer layer. The procedural step is terminated by stopping the GaCl supply.
The preparation of GaCl may be performed by contacting HCl and metallic gallium typically at temperatures of 700° C. to 1000° C. The direct contact of the starting substrate with GaCl, or optionally HCl not reacted during the formation reaction, does not hamper the process.
Alternatively, an AlN layer by using aluminum instead of gallium, or an AlₓGa₁₋ₓN-layer by using aluminum and gallium may be produced also.

During the subsequent process steps, the formed surface is further stabilized by a nitrogen compound-containing atmosphere, i.e. a decomposition of the formed nucleation layer is avoided. The nucleation layer at the same time protects the LiAlO₂ surface against process gases of the subsequent step(s).
For the growth of a thick GaN or AlₓGa₁₋ₓN-layer, the temperature is increased to 900° C. to 1050° C., wherein high growth rates of typically 30 μm/h to 250 μm/h are used for the growth of the layer, which is carried out by supplying GaCl, AlCl or a mixture of GaCl and AlCl. For the growth of the thick layer alone with the indicated temperatures, a minimum layer thickness of ca. 100 μm is necessary. The growth rate is controlled by the flow rates of GaCl or AlCl and the nitrogen supply, e.g. ammonia (NH₃). The minimum layer thickness is necessary in order to subsequently obtain a free-standing GaN layer. The process is not limited to a possible layer thickness above 100 μm.
The growth temperature and the carrier gas composition may be changed during the subsequent growth of the GaN or AlₓGa₁₋ₓN layer, whereby the crystal properties of GaN can be further improved e.g. at higher temperature (1000° C. to 1150° C.)
It is possible to add aluminum or indium for producing mixed crystal substrates, or of indium as a so-called surfactant for improving surface morphology.
An n-doping of the growing group III nitrides may be achieved by the reaction of silicon with hydrogen chloride, or particularly simple by the addition of the silicon-containing compound dichlorosilane (Cl₂SiH₂)
A p-doping of the growing group III nitride may be achieved by the reaction of magnesium Mg with hydrogen chloride, or by the addition of a magnesium-containing compound, e.g. biscyclopentadienyl magnesium (Cp₂Mg: Mg(C₅H₅)₂), into the gas phase.
A doping of the growing group III nitride for achieving semi-insulating electric properties may be achieved by the reaction of iron (Fe) with hydrogen chloride, or by the addition of an iron-containing compound, e.g. biscyclopentadienyl iron (ferrocen: Cp₂Fe: Fe(C₅H₅)₂), into the gas phase.
The use of a doping gas, compared to a solid source, simplifies the process, because a doping gas can be continuously controlled.

Since the growth temperature lies above the stabilization temperature of LiAlO₂ of ca. 900° C., a decomposition process of the starting substrate already starts during the GaN growth. Therefore, the high growth rate of the HVPE is important for the process. This decomposition process, with releasing lithium, leads to a decrease of the mechanical stability of the starting substrate and to a weakening of the bonding between the GaN layer or AlₓGa₁₋ₓN layer and LiAlO₂.
The decomposition process can be accelerated by the addition of hydrogen into the carrier gas, or by a temperature increase up to 1200° C.
In particular, this step for accelerating the in situ-separation of the starting substrate LiAlO₂ may be carried out after the proper growth of GaN or AlₓGa₁₋ₓN in the nitrogen compound-containing atmosphere.
Hydrogen has the property of reducing or avoiding the formation of cracks during growth of GaN or AlₓGa₁₋ₓN, however acting destructively on the LiAlO₂ starting substrate.
The process terminates with cooling the GaN layer or the AlₓGa₁₋ₓN layer and the starting substrate. Here, the GaN layer or the AlₓGa₁₋ₓN layer and the LiAlO₂ starting substrate separate definitely, wherein the LiAlO₂ starting substrate tears in stripes. Due to the separation, the then free-standing GaN layer or free-standing AlₓGa₁₋ₓN layer is not imposed with a bowing or warpage by the different thermal extension coefficients of substrate and layer.

The obtained free-standing GaN layer or l AlₓGa₁₋ₓN layer may be further used as GaN substrate or AlₓGa₁₋ₓN substrate for the growth of group III nitride layer structures in the MOVPE or in the MBE, or by applying metal contacts for the manufacture of electronic or opto-electronic devices. For this, the surface may be polished. The GaN substrate or the AlₓGa₁₋ₓN substrate may also be used as a starting layer for the further growth of group III nitrides by HVPE.

The process is characterized by its simplicity, and its application is thereby technologically particularly interesting. The simplicity resides in that only one HVPE apparatus is required, with relatively cheap starting substances for the whole process, and in that no subsequent steps are required for separating the starting substrate.

In the following, the invention will be explained by way of embodiment examples. In the associated drawings,

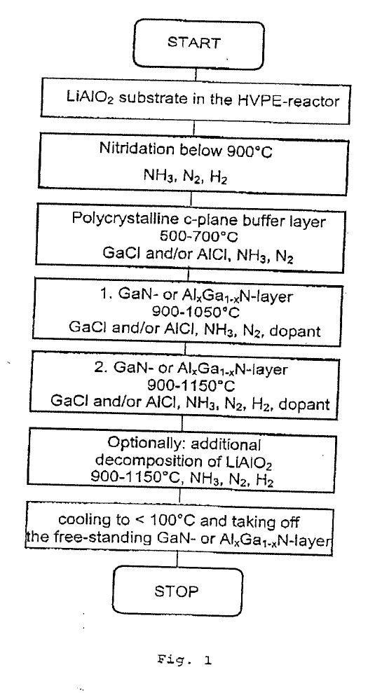

FIG. 1 shows a flow chart of the process,

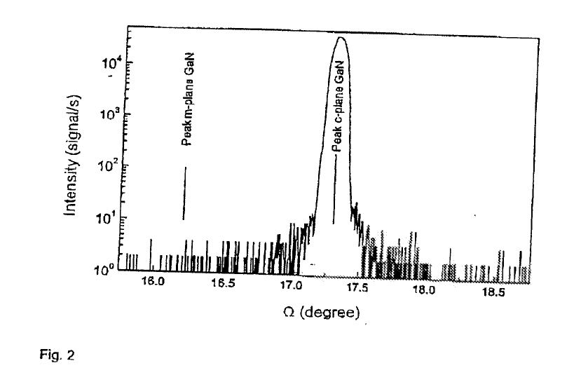

FIG. 2 shows an omega rocking curve of the 002 reflex of a free-standing GaN layer produced according to the process of the invention, including the proof of the c-plane orientation, wherein the expected peak position in case of an m-plane oriented GaN layer is indicated for clarification,

FIG. 3 shows a scheme of a GaN layer,

FIG. 4 shows basic vectors of the GaN lattice and the c-planes, and

FIG. 5 shows the basic vectors of the GaN lattice and the m-planes.

For example, a c-plane oriented GaN layer having a diameter of 50.8 mm is produced by the process. A commercial horizontal HVPE reactor is used. The LiAlO₂ substrate is charged into the reactor. The substrate holder rotates. The reactor pressure is adjusted to 800 hPa, and the temperature is adjusted to 850° C. The nitridation is carried out with a duration of 10 min. The nitrogen compound-containing atmosphere was achieved by a mixture of ammonia (600 ml/min), nitrogen and hydrogen. Subsequently, the substrate temperature is reduced to 600° C. in pure nitrogen atmosphere. By supplying NH₃ (500 ml/min) and HCl (10 ml/min), which reacts with gallium to GaCl, a GaN nucleation layer is grown within 7 min. This growth step is terminated by stopping the supply of HCl. In this event, the reactor pressure is reduced to 200 hPa, and the temperature is increased to 1000° C. It is also possible to continue the process at another pressure, e.g. unchanged at 800 hPa. Then, a first, single-crystalline GaN layer is initially grown in nitrogen atmosphere at flow rates of 500 ml/min for NH₃ and 30 ml/min for HCl. In the present case, this GaN layer is ca. 20 μm thick. Then, the temperature is subsequently increased to 1010° C. and the HCl-flow is increased to 100 ml/min at the same NH₃-flow, and the growth is continued for 60 min under the supply of hydrogen. The GaN layer and the substrate are then cooled down. At about 700° C., the supply of NH₃ is turned off. The then 160 μm thick, free-standing GaN layer (the LiAlO₂ substrate then has been self-separated) is taken out from the reactor, and the LiAlO₂ residues are discarded.

1. Process for producing c-plane oriented GaN- or AlₓGa₁₋ₓN-substrates, with using a starting substrate, characterized by the following steps:
use of a tetragonal (100) or (−100) oriented LiAlO₂ starting substrate,
nitridation in a nitrogen compound-containing atmosphere at temperatures below the decomposition temperature of LiAlO₂,
growth of a nucleation layer at temperatures from 500° C. to 700° C. by supplying GaCl or AlCl or a mixture of GaCl and AlCl in a nitrogen compound-containing atmosphere,
growth of a single-crystalline, c-plane oriented GaN or AlₓGa₁₋ₓN on the nucleation layer at temperatures in the range of between 900° C. and 1050° C. by hydride vapor phase epitaxy (HVPE) with GaCl or AlCl or a mixture of GaCl/AlCl in a nitrogen compound-containing atmosphere,
cooling the substrate.

2. Process for producing c-plane oriented GaN- or AlₓGa₁₋ₓN-substrates according to claim 1, wherein, after the growth step at 900 to 1050° C. and before cooling the substrate, a further growth step is carried out for depositing c-plane oriented GaN- or AlₓGa₁₋ₓN-layer by HVPE with a total thickness of at least 100 μm at temperatures between 1000 and 1150° C.

3. Process according to claim 1, characterized by a growth rate of at least 30 μm/h during growth of the thick GaN- or AlₓGa₁₋ₓN-layer.

4. Process according to claim 1, characterized by a hydrogen addition during or after the growth of the thick GaN- or AlₓGa₁₋ₓN-layer.

5. Process according to claim 1, characterized by, after the growth of the thick GaN- or AlₓGa₁₋ₓN-layer, a further temperature increase up to maximally 1200° C. in a nitrogen compound-containing atmosphere.

6. Process according to claim 1, characterized by an addition of aluminum (Al) or indium (In) during the growth of the thick GaN- or AlₓGa₁₋ₓN-layer.

7. Process according to claim 1, wherein a n-type doping is carried out by dichlorosilane (Cl₂SiH₂).

8. Process according to claim 1, wherein a p-type doping is carried out by magnesium (Mg or Mg(C₅H₅)₂).

9. Process according to claim 1, wherein a semi-insulating doping is carried out by iron (Fe or Fe(C₅H₅)₂).

10. Use of a substrate produced by a process according to claim 1 for a subsequent deposition of at least one further layer by MOVPE or MBE for the manufacture of electronic or opto-electronic devices, or for further use as substrate in HVPE.

11. Use of a substrate produced according to claim 1 for the manufacture of an electronic or opto-electronic device by applying at least one metal contact.

12. Use of a substrate produced by a process according to claim 1 for the subsequent deposition, by HVPE, of further GaN- or AlₓGa₁₋ₓN-layers for the manufacture of thicker GaN- or AlₓGa₁₋ₓN-layers or GaN- or AlₓGa₁₋ₓN-single crystals, which are subsequently separated e.g. by sawing, for the manufacture of electronic or opto-electronic devices, or for further use as substrate in HVPE.
